(19) United States
(12) Patent Application Publication
(10) Pub. No.: US 2008/0266986 A1
(43) Pub. Date: Oct. 30, 2008

(54) TIMING IMPROVEMENTS BY DUAL OUTPUT SYNCHRONIZING BUFFER

(76) Inventor: Dean B. SCHILLING, Fort Collins, CO (US)

Correspondence Address: HEWLETT-PACKARD COMPANY;Intellectual Property Administration, P.O. Box 272400, Fort Collins, CO, 80527-2400, US

(21) Appl. No.: 11/741,886

(22) Filed: Apr. 30, 2007

(51) Int. Cl. G11C 7/10

(52) U.S. Cl. 365/189.05

(57) ABSTRACT

Provided are a system and method for timing improvements by dual output synchronizing buffer. The method comprises providing at least two outputs on a synchronizing first-in-first-out buffer (“FIFO”) in a combinational logic circuit. The method further includes latching data into the FIFO. The method also includes alternating which of the two outputs by which the data is latched out of the FIFO, thereby extending timing in the combinational logic circuit.

### BACKGROUND

In digital designs, timing closure is an important part of the overall design. Multi-bit busses may be synchronized using synchronizing first-in-first-out (“FIFO”) buffers. When a design requires additional time to process data coming out of a FIFO buffer, the concept of a “resolver shadow” is implemented to insert additional time in combinational logic following a synchronizer. The concept relies on the fact that when data is enqued into a buffer, a shadow cycle becomes available to utilize for evaluation or synchronizing.

Specifically, as data is valid from the time that the data is written to the buffer (typically a full cycle before a pointer indicates that the data is valid), the shadow cycle may be utilized to correct for timing and synchronization problems in integrated circuits. However, the shadow is realized only when dequeing the first piece of data from the buffer, and once there is more than one piece of data in the buffer, only one cycle is available per dequeue.

### BRIEF DESCRIPTION OF THE DRAWINGS

For a detailed description of exemplary embodiments of the invention, reference will now be made to the accompanying drawings in which:

FIG. 1 shows a block diagram of an illustrative dual output synchronizing buffer logic in accordance with the present disclosure; and

FIG. 2 illustrates a flowchart of a method for timing improvements by a dual output synchronizing buffer in accordance with the present disclosure.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

The present disclosure is directed to utilizing a dual output, first-in-first-out (“FIFO”) buffer to provide additional timing in combinational logic, thereby curing certain timing and synchronizing problems previously unsolved by resolver shadows lasting a single cycle. One of the FIFO outputs is the data pointed to by the read pointer, while the other output is the next data to be read out. A select signal determines which of the two outputs is used. To utilize the shadow, two parallel cones of logic are connected to each output, and combined (e.g., muxed together) prior to the subsequent latch via the select signal. As such, each path has a minimum evaluation time of at least one cycle plus resolver uncertainty, and each deque from the FIFO buffer may use the resolver shadow to buy additional time, up to 1½ to 2½ cycles, depending on resolver delay and input to output clock skew.

Following is the basic description of a synchronizing FIFO of the prior art. The signals connected to a typical, single output, synchronizing FIFO come from two different clock domains. The write clock domain contains various signals. The write clock domain includes inputs: “in_clk” that is a clock signal, “in_reset” that indicates when to reset the registers, “in_data” that includes the data to be passed through the FIFO, and “enq” that indicates when to write the “in_data” to the registers, and outputs: “full” that indicates when the registers of the buffer are all full. The read clock domain contains also contains various signals. The read clock domain inputs include: “out_reset” that indicates when to reset the registers, and “deq” that indicates when to the write the data out of the registers, and the read clock domain outputs include: “out_data” that includes the data to be passed out of the FIFO, and “empty” that indicates that the registers of the buffer are empty.

In operation, both sides of the single output synchronizing FIFO are reset using the appropriate reset signals to clear out the write and read pointers, so both point to entry 0. When both the read pointer and write pointer match, the “empty” signal is asserted high. When the difference between the read and write pointers equals the depth of the FIFO, the “full” signal is asserted high. Typically, the read and write pointers have one more bit than the minimum based on the depth, to resolve the ambiguity of matching pointers indicating empty or full (i.e: for an 8 entry deep FIFO, only 3 bits are needed for the pointers). If the pointers “match,” it could indicate either a full or empty condition.

As long as the “full” signal is deasserted, data can be written into the single output FIFO. When writing data into the FIFO, the data is driven into “in_data” and the “enq” signal is asserted high. When the “enq” signal is sampled high, the data is written into the latch array, and the write pointer is incremented. The write pointer is then grey coded, synchronized into the read clock domain and binary encoded. The write pointer is then compared to the read pointer. Since the write pointer is currently greater than the read pointer, the “empty” signal is de-asserted low.

Once the read clock domain detects that the “empty” signal is deasserted low, the “out_data” may be used (i.e., the data is valid for use on the backend of the FIFO) and “deq” is asserted high. When the “deq” signal is sampled high, the read pointer is incremented. The read pointer is then grey coded, synchronized into the write clock domain and binary encoded. The read pointer is then compared to the write pointer. As long as the difference between the read and write pointers is less than the depth of the FIFO, the “full” signal is de-asserted low.

If more than one data entry is currently written into the FIFO, data can be read out of the FIFO on each read clock until the empty signal is asserted high. This is why the output timing budget is single cycle.

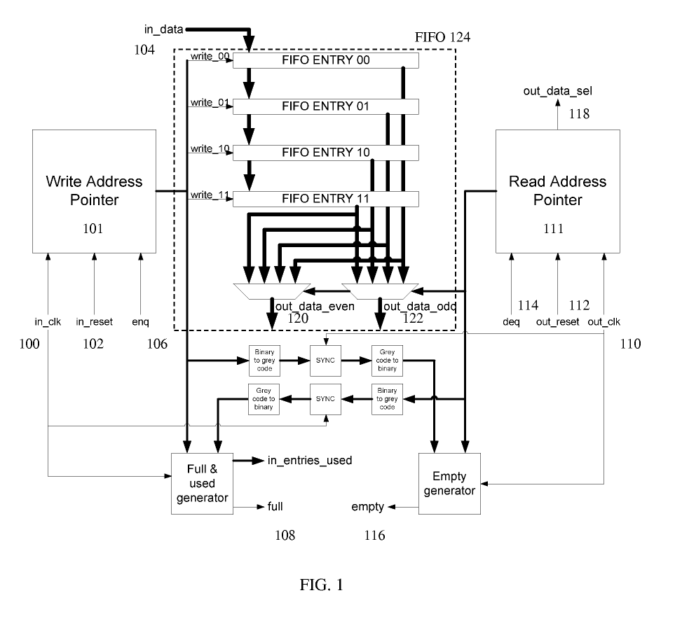

By comparison, the dual output synchronizing FIFO of the present disclosure employs a single input, dual output latch array. FIG. 1 shows a block diagram of an illustrative dual output synchronizing buffer logic in accordance with the present disclosure. The depth of the FIFO 124 shown in FIG. 1 is 4 registers, though in embodiments of the present disclosure, a FIFO of any practicable depth may be employed. The addition of a second data output port and a select signal enables an increase in the output timing budget beyond a single cycle. The write clock domain includes inputs: “in_clk” 100 that is the clock signal, “in_reset” 102 that indicates when to reset the registers, “in_data” 104 that includes the data to be passed through the FIFO, and “enq” 106 that indicates when to write the “in_data” 104 to the registers, and outputs: “full” 108 that indicates when the registers of the buffer are all full. The read clock domain inputs include: “out_clk” 110 that is the clock signal out, “out_reset” 112 that indicates when to reset the registers, and “deq” 114 that indicates when to the write the data out of the registers, and the read clock domain outputs include: “out_data_even” 120 and “out_data_odd” 122 that includes the data to be passed out of the FIFO alternatingly, a select signal “out_data_sel” 118 that provides an indication of whether to read out the data from the even output 120 or the odd output 122, and “empty” 116 that indicates that the registers of the buffer are empty.

When the first piece of data is enqued into the dual output synchronizing FIFO of the present disclosure, the data is latched into the latch array and shows up on the “out_data_even” port 120. At the same time, the “out_data_sel” 118 signal is set to the value of 0. This data enqued into the FIFO is available from the time it shows up on the “out_data_even” 120 port until the “empty” 116 signal is deasserted low, which is greater than 1 cycle, just like the case of the first write to a standard synchronizing FIFO as discussed above. When the second piece of data is enqued into the FIFO, the data is latched into the latch array and shows up on the “out_data_odd” port 122. This second piece of data will also be available in the read clock domain for greater than 1 cycle because of the synchronizing delay of the write pointer. In preferred embodiments, the data is available in the read clock domain for at least 1½ to 2½ cycles. Subsequent writes alternate between even and odd entries of the latch array.

The timing savings are the result of having two parallel branches of logic off of each of the out_data ports 120, 122. The two parallel branches of logic from the out_data ports 120, 122 may then be combined in a mux controlled by the select signal “out_data_sel” 118, and fed to a latch qualified by the “empty” signal 116.

Thus, even if more than one data entry is written into the FIFO, data can be read out of the FIFO on each read clock until the “empty” signal 116 is asserted high, which will be longer than a single cycle. This is why the output timing budget is improved.

Some advantages of the present disclosure are that timing may be improved without adding additional states to the logic and without forcing improvements in the timing of the logic that comes after the synchronizer. Certain latencies can thus be cured.

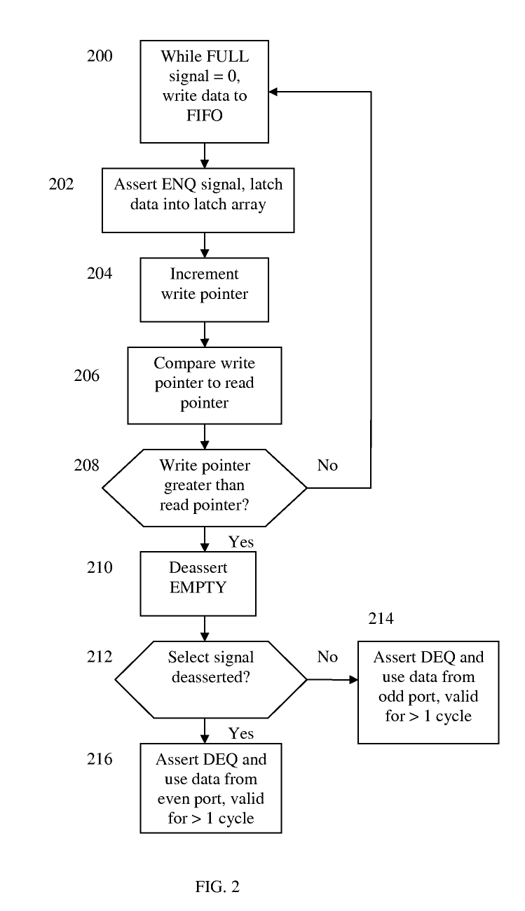

Referring now to FIG. 2, a flowchart is shown of a method for timing improvements by a dual output synchronizing buffer. While the “full” 108 signal is low, the data is written to the dual output FIFO 124 as in_data 104 (block 200). The method continues with asserting the “enq” signal, and latching the data into the latch array (block 202). The write pointer is incremented (204). The method continues with a comparison of the write pointer to the read pointer (block 206). A determination is made as to whether the write pointer is greater than the read pointer (block 208). If not, the “full” signal 108 remains deasserted, returning to block 200. If the write pointer is greater than the read pointer, the “empty” signal 116 is deasserted.

A determination is made at block 212 as to whether the select signal out_data_sel 118 is deasserted, and if not, the “deq” signal is asserted, and data from the odd port is used. The data from out_data_odd is valid for greater than one timing cycle. If the select signal out_data_sel 118 is asserted, the “deq” signal is asserted, and the data from the even port is used. The data from out_data_even is valid for greater than one timing cycle. The method can continue repeating as long as there is data moving in and out of the FIFO.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A system, comprising:
a plurality of multi-bit busses;
a synchronizing FIFO buffer, the FIFO buffer comprising:
an input port that receives input data;
a plurality of registers into which the input data is latched;
at least two output ports, driven by a select signal, out of which the input data is latched;
wherein the data is latched out of the two output ports alternatingly, thereby extending a timing budget for synchronizing the plurality of multi-bit busses.

2. The FIFO buffer according to claim 1, further comprising a write address pointer that is incremented each time a piece of data is latched into a register of the FIFO, and a read address pointer that is incremented each time a piece of data is latched out of a register of the FIFO.

3. The FIFO buffer according to claim 2, further comprising a FULL indicator that is asserted when the FIFO registers are full.

4. The FIFO buffer according to claim 3, wherein the FIFO registers are full when the difference between the read address pointer and the write address pointer is less than the depth of the FIFO.

5. The FIFO buffer according to claim 2, further comprising an EMPTY indicator that is asserted when the FIFO registers are empty.

6. The FIFO buffer according to claim 5, wherein the FIFO registers are empty when the write address pointer points to the same address as the read address pointer.

7. A first-in-first-out (“FIFO”) buffer, comprising:
an input port that receives input data;
a plurality of registers into which the input data is latched;
at least two output ports, driven by a select signal, out of which the input data is latched;
wherein the data is latched out of the two output ports alternatingly, thereby extending an amount of time spent in the FIFO buffer.

8. The FIFO buffer according to claim 7, further comprising a write address pointer that is incremented each time a piece of data is latched into a register of the FIFO, and a read address pointer that is incremented each time a piece of data is latched out of a register of the FIFO.

9. The FIFO buffer according to claim 8, further comprising a FULL indicator that is asserted when the FIFO registers are full.

10. The FIFO buffer according to claim 9, wherein the FIFO registers are full when the difference between the read address pointer and the write address pointer is less than the depth of the FIFO.

11. The FIFO buffer according to claim 8, further comprising an EMPTY indicator that is asserted when the FIFO registers are empty.

12. The FIFO buffer according to claim 11, wherein the FIFO registers are empty when the write address pointer points to the same address as the read address pointer.

13. A method, comprising:
providing at least two outputs on a synchronizing first-in-first-out buffer (“FIFO”) in a combinational logic circuit;
latching data into the FIFO; and
alternating which of the two outputs by which the data is latched out of the FIFO, thereby extending timing in the combinational logic circuit.

14. The method according to claim 13, further comprising latching data into the FIFO until the FIFO is full.

15. The method according to claim 14, wherein the FIFO registers are full when the difference between the read address pointer and the write address pointer is less than the depth of the FIFO.

16. The method according to claim 13, further comprising latching data out of the FIFO until the FIFO is empty.

17. The method according to claim 16, wherein the FIFO registers are empty when the write address pointer points to the same address as the read address pointer.

18. The method according to claim 13, further comprising providing a select signal to indicate which of the two outputs by which a particular piece of data is latched out of the FIFO.

19. The method according to claim 18, further comprising combining the two outputs in a mux controlled by the select signal.

20. The method according to claim 18, wherein alternating which of the two outputs by which the data is latched out of the FIFO further comprises latching data out of the first output of the FIFO when the select signal is asserted, and latching data out of the second output of the FIFO when the select signal is deasserted.

21. The method according to claim 17, further comprising grey coding, synchronizing, and binary encoding the write address pointer for comparison to the read address pointer.

22. The method according to claim 15, further comprising grey coding, synchronizing, and binary encoding the read address pointer for comparison to the write address pointer.
